(19) United States
(12) Patent Application Publication
(10) Pub. No.: US 2024/0265175 A1
(43) Pub. Date: Aug. 8, 2024

(54) VARIABLE OPTIMIZATION SYSTEM

(71) Applicant: NIPPON TELEGRAPH AND TELEPHONE CORPORATION, Tokyo (JP)

(72) Inventors: Kenta NIWA, Tokyo (JP); Hiroshi SAWADA, Tokyo (JP); Akinori FUJINO, Tokyo (JP); Noboru HARADA, Tokyo (JP)

(73) Assignee: NIPPON TELEGRAPH AND TELEPHONE CORPORATION, Tokyo (JP)

(21) Appl. No.: 18/561,969

(22) PCT Filed: May 28, 2021
(86) PCT No.: PCT/JP2021/020341

§ 371 Date: Nov. 17, 2023

(51) Int. Cl. G06F 30/27

(52) U.S. Cl. CPC G06F 30/27

(57) ABSTRACT

A technique for stably optimizing a variable of model so as to conform the learning data set is provided, even when there is a statistical deviation in a learning data set distributed and accumulated in a plurality of nodes, or communication between nodes is asynchronous and sparse. The i-th node includes a model variable update unit that updates a value of a model variable wᵢ by an expression using a control variable in a stochastic variance reduced gradient method, a first dual variable update unit that updates a value of a dual variable y_{i|j} by a predetermined expression with respect to a predetermined index j, a second dual variable update unit that receives a value of the model variable wⱼ and a value of the dual variable y_{j|i} from the j-th node and updates a value of the dual variable z_{i|j} and a value of the global control variable ⁻cᵢ by a predetermined expression, and a local control variable update unit that update a value of a local control variable c_{i|i} and a temporary variable u_{i|i} of the i-th node by a predetermined expression when execution of update processing is the K-th in the r-th round.

### TECHNICAL FIELD

The present invention relates to a technique for optimizing a model variable serving as a machine learning target.

### BACKGROUND ART

In recent years, it has been actively performed to extract meaningful information from data by using a framework of machine learning such as deep learning. In the framework of machine learning, usually, a model is learned after obtained data are collected in one place.

However, data used for learning may not be collected in one place. (1) For example, when the data used for learning has high privacy and confidentiality such as data related to medical care, and the data cannot be outputted to the outside, the data cannot be collected in one place. Further, (2) for example, when the number of devices for storing data used for learning is too large, such as data inherent in a car or a smart phone, there is a possibility that a network is compressed by data transfer, and in this case, data cannot be collected in one place. Furthermore, (3) there has been an example in which severe regulations are imposed on the handling of data, such as the general data protection regulation (GDPR) in the EU, and in some cases, data cannot be collected in one place. That is, from the viewpoint of privacy protection, increase of data amount, and legal regulation, an era in which learning is performed in a distributed situation will come in the future.

Therefore, at present, a concept such as edge computing capable of learning even when data cannot be collected in one place has been studied (see NPL 1). In the edge computing, a model is learned in a state where data used for learning is accumulated in each of computers (also referred to as nodes) distributed on the network. Basic requirements for the edge computing are the followings.

(1) A model equivalent to a model learned after all data are collected in one place (hereinafter referred to as a global model) is obtained.

In this case, it is required for the edge computing to satisfy the following three requirements.

(2) An arbitrary network structure can be used so that the scale of data processing can be extended to an arbitrary scale. As the network structure, there are, for example, a distributed network provided with a server and a network of P2P type communication.

(3) Even if statistically biased data (referred to as non-uniform data) is accumulated in each node, learning is stably performed.

(4) Learning is stably performed without synchronous communication of all nodes constituting the network. The object of communication in this case is not data accumulated in each node, but auxiliary information such as a model update difference.

Learning in the edge computing will be described below. Consider a network in which N nodes (N is an integer of 2 or more) are connected. Since the network structure can be an arbitrary structure, it is described by using a graph, and a network for performing edge computing is represented as a graph G (N, ε). Here, N={1, 2, . . . , n} represents an index set representing nodes constituting the network, ε={1, 2, . . . , E} (E is an integer of 1 or more) is an index set representing edges constituting the network. Note that each node is connected to one or more nodes. That is, it is assumed that there is no isolated node. Also, if εᵢ={j∈N|(i, j)∈(j≠i)} is satisfied, εᵢ represents an index set of nodes to which the i-th node is connected.

FIG. 1 is a diagram showing a network in which 4 nodes are connected. In FIG. 1, the i-th node is represented as Node #i. In addition, for example, ε₄={1, 3} indicates that the fourth node is connected to the first node and the third node.

Hereinafter, the model variable learned at the i-th node is defined as wᵢ. Further, a learning data set which is a set of learning data accumulated in the i-th node is defined as xᵢ.

The model to be optimized has the same structure and dimension for all nodes from the requirement (1). That is, model variables wᵢ(i=1, 2, . . . , n) are learned so as to satisfy wᵢ=wⱼ with respect to arbitrary i, j (i≠j). Also, from the requirement (3), the learning data set xᵢ and the learning data set xⱼ (i≠j) are generally different in terms of the number of data and the statistical property of data.

It is assumed that the calculation capability of each node may be different. However, in the following description, for simplification of the description, auxiliary information such as a variable update difference is exchanged once at each edge including a specific node while the variable is updated K times by the specific node in learning. Hereinafter, the unit of the series of update and exchange processing will be referred to as a round. However, the exchange timing may be random. It is assumed that the round is executed R times.

FIG. 2 shows the state of edge computing in the network shown in FIG. 1. In FIG. 2, the learning state is shown in the case where a specific node is defined as Node #1 and K=8 and R=2 are satisfied. In FIG. 2, “U” represents variable update processing in the node, and “X” represents data exchange processing between nodes. Note that, generally, no special restriction (for example, a restriction on the calculation speed of the node) on the variable update processing in the node or no special restriction (for example, a restriction on the communication method) on the data exchange processing between the nodes is required, and the number of times of the variable update processing in the node and the number of times of the data exchange processing between the nodes are not required to be uniform.

Hereinafter, a set representing the number of times of execution of the round is represented as {1, 2, . . . , R}, and a set representing the number of times of execution of the update processing is represented as {1, 2, . . . , K}. Further, εᵢ^{r,k} (r∈{1, 2, . . . , R}, k∈={1, 2, . . . , K}) represents an index set of nodes in which the i-th node is a communication target in the k-th update processing in the r-th round.

In the learning by the edge computing, under a condition that wᵢ=wⱼ is satisfied for any i, j (i≠j), that is, model variables of all nodes match, a model minimizing a cost function f is searched.

Hereinafter, the cost function will be described. In the assumption that the neural network structure and the definition of the cost function are common to all nodes, and if fᵢ is a cost function in the i-th node, fᵢ=fⱼ is satisfied for arbitrary i and j (i≠j). Tin addition, a parameter of the cost function fᵢ is the model variable wᵢ to be learned. The cost function fᵢ is appropriately designed for each application field such as image classification, noise removal, image generation, voice recognition, and abnormality detection, and it is generally possible to use an arbitrary differentiable function as the cost function fᵢ. That is, if the cost function fᵢ is a differentiable function, it may be a convex function or a non-convex function.

Here, as a specific example, a cost function using deep learning will be described. The design of the cost function using the deep learning has been widely used in recent years, and the cost function using the deep learning is a differentiable non-convex function. This will be described by way of an example of image classification. The image classification model is a model (that is, a function) for obtaining an output value yᵢ from an input image xᵢ through a neural network (that is, a combination of a multi-layer linear transformation and a non-linear transformation). The output value yᵢ is a C-dimensional one-hot vector representing an existence probability for each class in the case where there are C classes to be classified. Note that the one-hot vector indicates that it is not the relevant class as an element value of the vector is close to 0, and that it is the relevant class as the element value of the vector is close to 1, and normally, the class having the maximum value is used as the classification result. Then, a function for outputting a scalar evaluation value is defined as an evaluation function, and a function obtained by combining the evaluation function with the function of the image classification model is defined as the cost function fᵢ. In a classification problem including image classification, a cross entropy function is often used as an evaluation function.

w=[wᵢ^{T}, . . . , wₙ^{T}]^{T} is set, and the cost function f is defined by the following expression.

$$f ( w ) = \frac{1}{n} {\sum }_{i = 1}^{n} {f}_{i} ( {w}_{i} ) \qquad [ Math . 1 ]$$

In addition, when gᵢ=∇fᵢ(wᵢ) is set, gᵢ is a function representing a gradient of the cost function fᵢ. When the gradient of the cost function fᵢ is calculated for the mini-batch selected as a part of the learning data set xᵢ accumulated in the i-th node, the gradient becomes a probability variable. Therefore, gᵢ may be referred to as a stochastic gradient of the cost function fᵢ. In the deep learning, a mini-batch is selected for generalization of the non-convex function, and learning is advanced in a small step size while fluctuating the gradient.

A method of solving an optimization problem for minimizing the cost of the following expression will be described below.

$${inf}_{w} f ( w ) \qquad [ Math . 2 ]$$

As the method for solving this optimization problem, there are, for example, methods called (1) average consensus building and (2) stochastic variance reduced gradient method (SVRG). Examples of average consensus building include DSGD, Gossip SGD and FedAvg. In addition, examples of stochastic variance reduced gradient method include SCAFFOLD and GT-SVR.

First, the DSGD will be described as an example of average consensus building. FIG. 3 shows an algorithm of the DSGD (see NPL 2). Here, μ represents a step size, and Eᵢ represents the number of elements of the set εᵢ. As shown in FIG. 3, the model variables are updated in each node and averaged at any time, so that the connected nodes have similar model variables (i.e., consensus is built). The average consensus building is often used in the edge computing as a basic algorithm because the amount of calculation and memory consumption are small.

Next, as an example of the stochastic variance reduced gradient method, a description will be given of the SCAFFOLD. FIG. 4 shows the algorithm of the SCAFFOLD (see NPL 3). SCAFFOLD is an algorithm in which SVR is applied to FedAvg which is the average consensus building in a centralized distributed network. In the stochastic variance reduced gradient method, by replacing the stochastic gradient gᵢ with −gᵢ of the following expression (1), the variance of the stochastic gradient can be reduced, and the destabilization of learning by the selection of the mini-batch is prevented.

$$\begin{matrix}[ Math . 3 ] & \\ {\overline{g}}_{i} ( {w}_{i} ) ← {g}_{i} ( {w}_{i} ) + {\overline{c}}_{i} - {c}_{i} & ( 1 )\end{matrix}$$

Here, ⁻cᵢ is a global control variable which is an expected value of the stochastic gradient of the i-th node and the node group connected to the node, and cᵢ is a local control variable which is an expected value of the stochastic gradient of the I-th node, and are defined by the following expressions, respectively.

$${\overline{c}}_{i} = {\sum }_{j ∈ {ε}_{i}} E [ {g}_{j} ( {w}_{i} ) ] + E [ {g}_{i} ( {w}_{i} ) ] \qquad [ Math . 4 ]$$

$${c}_{i} = E [ {g}_{i} ( {w}_{i} ) ] \qquad [ Math . 5 ]$$

That is, the expression (1) is an expression for correcting a direction of learning toward a global model by adding a difference between the global control variable ⁻cᵢ and the local control variable cᵢ to the stochastic gradient gᵢ.

Note that as can be seen from FIG. 4, the global control variable ⁻cᵢ and the local control variable cᵢ are also updated by a predetermined update rule.

### CITATION LIST

### Non Patent Literature

[NPL 1] NTT data corporation, “Attractive “edge computing” in the IoT era”, [online], [retrieved on May 10, 2021], Internet <URL: https://www.nttdata.com/jp/ja/data-insight/2018/1122/>
[NPL 2] J. Chen, A. H. Sayed, “Diffusion adaptation strategies for distributed optimization and learning over networks”, IEEE Transactions on Signal Processing, 60(8), pp. 4289 to 4305, 2012.
[NPL 3] S. P. Karimireddy, S. Kale, M. Mohri, S. Reddi, S. Stich, A. T. Suresh, “SCAFFOLD: Stochastic Controlled Averaging for Federated Learning,” Proceedings of the 37th International Conference on Machine Learning, PMLR 119: 5132-5143, 2020.

### SUMMARY OF INVENTION

### Technical Problem

The average consensus building such as DSGD operates stably when the learning data set accumulated in each node is approximately statistically homogeneous. On the other hand, there is a problem in that it often does not operate well in the case where (1) there is a statistical deviation in the learning data set accumulated between nodes or (2) communication between nodes is asynchronous and sparse. This problem is because the stochastic gradient takes a considerably different value for each node, so that the direction of learning is not corrected so as to approach the global model.

In addition, since the variable is updated to reduce the variance of the stochastic gradient in the stochastic variance reduced gradient method such as SCAFFOLD, the probability variance reduction gradient method has a strong resistance to (1) the statistical deviation of the data set for learning accumulated between nodes or (2) the case where communication between nodes is asynchronous and sparse compared with the averaging agreement formation. On the other hand, due to the update rules of the two control variables, the expected value of the stochastic gradient may not be estimated with high accuracy, and in such a case, there is a problem that the learning cannot be stably advanced and the global model cannot be learned.

Then, an object of the present invention is to provide a technique for stably optimizing a variable of model so as to conform the learning data set in the case where the learning data set distributed and accumulated in a plurality of nodes has the statistical deviation or the communication between nodes is asynchronous and sparse.

### Solution to Problem

An aspect of the present invention is a variable optimization system that constituted by n (n is an integer 2 or more) nodes and optimizes a model variable by using a learning data set that is a learning data set accumulated in each node, in which N={1, . . . , n} is an index set of nodes, i∈N is set, wᵢ is a model variable in the i-th node, xᵢ is a learning data set in the i-th node, fᵢ(wᵢ) is a cost function in the i-th node, εᵢ is an index set of nodes to which the i-th node is connected, ⁻cᵢ is a global control variable in the i-th node, c_{i|i} is a local control variable in the i-th node, y_{i|j} and z_{i|j}(j∈sᵢ) are dual variables in the i-th node corresponding to the j-th node, respectively, A_{i|j}(j∈sᵢ) is a parameter matrix defined by the following expression,

$${A}_{i \vert j} = \{ \begin{matrix}I ( i > j ) \\ - I ( i < j )\end{matrix} \qquad [ Math . 6 ]$$

R and K are integers of 1 or more, respectively, {1, 2, . . . , R} is a set representing the number of times of execution of a round, {1, 2, . . . , K} is a set representing the number of times of execution of update processing, εᵢ^{r,k}(r∈{1, 2, . . . , R}, k∈{1, 2, . . . , K}) is an index set of nodes to be communicated by the i-th node in the k-th update processing in the r-th round, the variable optimization system includes, a model variable update unit that updates a value of the model variable wᵢ in the i-th node by the following expression,

$${g}_{i} ( {w}_{i} ) ← ∇ {f}_{i} ( {w}_{i} ) \qquad [ Math . 7 ]$$

(where, ∇fᵢ(wᵢ) is calculated using a mini-batch x_{i,MB} which is a subset of the learning data set xᵢ)

$${\overline{g}}_{i} ( {w}_{i} ) ← {g}_{i} ( {w}_{i} ) + {\overline{c}}_{i} - {c}_{i \vert i} \qquad [ Math . 8 ]$$

$${w}_{i} ← \frac{( μ {w}_{i} - {\overline{g}}_{i} ( {w}_{i} ) + {\sum }_{j ∈ {ε}_{i}} {β}_{i \vert j} ( sgn ( {A}_{i \vert j} ) η \cdot {z}_{i \vert j} + ρ \cdot {u}_{i \vert j} ) )}{( μ + η + ρ )} \qquad [ Math . 9 ]$$

(where, μ, η and ρ are predetermined vectors, β_{i|j} is a weight in the i-th node corresponding to the j-th node, u_{i|j} is a temporary variable in the i-th node corresponding to the j-th node, and sign (A_{i|j}) is a sign of an identity matrix A_{i|j}), a first dual variable update unit that updates a value of a dual variable y_{i|j} by the following expression for an index j satisfying j∈εᵢ,

$${y}_{i \vert j} ← {z}_{i \vert j} - 2 sgn ( {A}_{i \vert j} ) {w}_{i} \qquad [ Math . 10 ]$$

a second dual variable update unit that receives, for an index j satisfying j∈εᵢ^{r,k}, a value of the model variable wⱼ and a value of the dual variable y_{j|i} from the j-th node, updates a value of the dual variable z_{i|j} by a predetermined expression, and updates a value of the global control variable ⁻cᵢ by the following expression,

$${u}_{i \vert j} ← {w}_{j} \qquad [ Math . 11 ]$$

$${c}_{i \vert j} ← {c}_{i \vert j} - {\overline{c}}_{i} + \frac{1}{K μ} ( {u}_{i \vert j} - {w}_{i} ) \qquad [ Math . 12 ]$$

$${\overline{c}}_{i} ← {\sum }_{j ∈ \{ i , {ε}_{i} \}} {β}_{i \vert j} {c}_{i \vert j} \qquad [ Math . 13 ]$$

a local control variable update unit that updates a value of the local control variable c_{i|i} and a value of the temporary variable u_{i|i} in the i-th node by the following expression when the execution of the update processing is the K-th in the r-th round, and

$${c}_{i \vert i} ← {c}_{i \vert i} - {\overline{c}}_{i} + \frac{1}{K μ} ( {u}_{i \vert i} - {w}_{i} ) \qquad [ Math . 14 ]$$

$${u}_{i \vert i} - {w}_{i} . \qquad [ Math . 15 ]$$

An aspect of the present invention is a variable optimization system that constituted by n (n is an integer 2 or more) nodes and optimizes a model variable by using a learning data set that is a learning data set accumulated in each node, in which N={1, . . . , n} is an index set of nodes, i∈N is set, wᵢ is a model variable in the i-th node, xᵢ is a learning data set in the i-th node, fᵢ(wᵢ) is a cost function in the i-th node, εᵢ is an index set of nodes to which the i-th node is connected, yᵢ|j and z_{i|j}(j∈εᵢ) are dual variables in the i-th node corresponding to the j-th node, respectively, A_{i|j}(j∈εᵢ) is a parameter matrix defined by the following expression,

$${A}_{i \vert j} = \{ \begin{matrix}I ( i > j ) \\ - I ( i < j )\end{matrix} \qquad [ Math . 16 ]$$

R and K are integers of 1 or more, respectively, {1, 2, . . . , R} is a set representing the number of times of execution of a round, {1, 2, . . . , K} is a set representing the number of times of execution of update processing, εᵢ^{r,k}(r∈{1, 2, . . . , R}, k∈{1, 2, . . . , K}) is an index set of nodes to be communicated by the i-th node in the k-th update processing in the r-th round, the variable optimization system includes, a model variable update unit that updates a value of the model variable wᵢ in the i-th node by the following expression,

$${g}_{i} ( {w}_{i} ) ← ∇ {f}_{i} ( {w}_{i} ) \qquad [ Math . 17 ]$$

(where, ∇fᵢ(wᵢ) is calculated using a mini-batch x_{i,MB} which is a subset of the learning data set xᵢ)

$${w}_{i} ← \frac{( μ {w}_{i} - {g}_{i} ( {w}_{i} ) + {\sum }_{j ∈ {ε}_{i}} {β}_{i \vert j} ( sgn ( {A}_{i \vert j} ) η \cdot {z}_{i \vert j} + ρ \cdot {u}_{i \vert j} ) )}{( μ + η + ρ )} \qquad [ Math . 18 ]$$

(where, μ, η and ρ are predetermined vectors, β_{i|j} is a weight in the i-th node corresponding to the j-th node, u_{i|j} is a temporary variable in the i-th node corresponding to the j-th node, and sign (A_{i|j}) is a sign of an identity matrix A_{i|j}), a first dual variable update unit that updates a value of a dual variable y_{i|j} by the following expression for an index j satisfying j∈εᵢ,

$${y}_{i \vert j} ← {z}_{i \vert j} - 2 sgn ( {A}_{i \vert j} ) {w}_{i} \qquad [ Math . 19 ]$$

a second dual variable update unit that receives, for an index j satisfying j∈εᵢ^{r,k}, a value of the model variable wⱼ and a value of the dual variable y_{j|i} from the j-th node, updates a value of the dual variable z_{i|j} by a predetermined expression, and updates a value of the temporary variable u_{i|j}, and

$${u}_{i \vert j} ← {w}_{j} \qquad [ Math . 20 ]$$

wherein
ψ is a distribution for each type of learning data accumulated in the n nodes, and a mini-batches x_{i,MB} is a mini-batch generated from the learning data set xᵢ in accordance with the distribution ψ.

An aspect of the present invention is a variable optimization system that constituted by n (n is an integer 2 or more) nodes and optimizes a model variable by using a learning data set that is a learning data set accumulated in each node, in which N={1, . . . , n} is an index set of nodes, i∈N is set, wᵢ is a model variable in the i-th node, xᵢ is a learning data set in the i-th node, fᵢ(wᵢ) is a cost function in the i-th node, εᵢ is an index set of nodes to which the i-th node is connected, y_{i|j} and z_{i|j}(j∈εᵢ) are dual variables in the i-th node corresponding to the j-th node, respectively, A_{i|j}(j∈εᵢ) is a parameter matrix defined by the following expression,

$${A}_{i \vert j} = \{ \begin{matrix}I ( i > j ) \\ - I ( i < j )\end{matrix} \qquad [ Math . 21 ]$$

R and K are integers of 1 or more, respectively, {1, 2, . . . , R} is a set representing the number of times of execution of a round, {1, 2, . . . , K} is a set representing the number of times of execution of update processing, εᵢ^{r,k}(r∈{1, 2, . . . , R}, k∈{1, 2, . . . , K}) is an index set of nodes to be communicated by the i-th node in the k-th update processing in the r-th round, the variable optimization system includes, a model variable update unit that updates a value of the model variable wᵢ in the i-th node by the following expression,

$${g}_{i} ( {w}_{i} ) ← ∇ {f}_{i} ( {w}_{i} ) \qquad [ Math . 22 ]$$

(where, ∇fᵢ(wᵢ) is calculated using a mini-batch x_{i,MB} which is a subset of the learning data set xᵢ)

$${w}_{i} ← \frac{( μ {w}_{i} - {g}_{i} ( {w}_{i} ) + {\sum }_{j ∈ {ε}_{i}} {β}_{i \vert j} ( sgn ( {A}_{i \vert j} ) η \cdot {z}_{i \vert j} + ρ \cdot {u}_{i \vert j} ) )}{( μ + η + ρ )} \qquad [ Math . 23 ]$$

(where, μ, η and ρ are predetermined vectors, β_{i|j} is a weight in the i-th node corresponding to the j-th node, u_{i|j} is a temporary variable in the i-th node corresponding to the j-th node, and sign (A_{i|j}) is a sign of an identity matrix A_{i|j}), a first dual variable update unit that updates a value of a dual variable y_{i|j} by the following expression for an index j satisfying j∈εᵢ,

$${y}_{i \vert j} ← {z}_{i \vert j} - 2 sgn ( {A}_{i \vert j} ) {w}_{i} \qquad [ Math . 24 ]$$

a second dual variable update unit that receives, for an index j satisfying j∈εᵢ^{r,k}, a value of the model variable wⱼ and a value of the dual variable y_{j|i} from the j-th node, updates a value of the dual variable z_{i|j} by a predetermined expression, and updates a value of the temporary variable u_{i|j}, and

$${u}_{i \vert j} ← {w}_{j} \qquad [ Math . 25 ]$$

wherein
dᵢ is the number of data of the learning data set xᵢ, and a weight β_{i|j} is the ratio π_{i|j} occupied by the number of data accumulated in the j-th node connected to the i-th node with respect to the number of data accumulated in all nodes connected to the i-th node and the i-th node is calculated by the following expression.

$${π}_{i \vert j} = \frac{{d}_{j}}{{\sum }_{j ∈ \{ ì , {ε}_{i} \}} {d}_{j}} \qquad [ Math . 26 ]$$

### Advantageous Effects of Invention

According to the present invention, even when there is a statistical deviation in a learning data set distributed and accumulated in a plurality of nodes, or communication between nodes is asynchronous and sparse, a variable of model can be stably optimized so as to conform to the learning data set.

### BRIEF DESCRIPTION OF DRAWINGS

FIG. 1 is a diagram showing an example of a network to which n (n=4) nodes are connected.

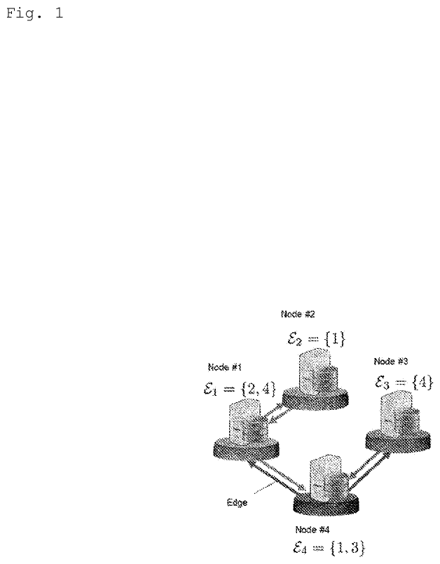

FIG. 2 is a diagram showing a state of edge computing in the network shown in FIG. 1.

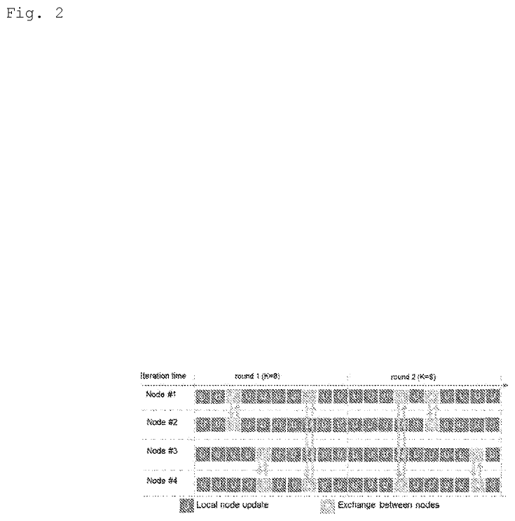

FIG. 3 is a diagram showing DSGD algorithm.

FIG. 4 is a diagram showing SCAFFOLD algorithm.

FIG. 5 is a diagram showing ECL algorithm.

FIG. 6 is a diagram showing an optimization algorithm of the present application.

FIG. 7 is a diagram showing the optimization algorithm of the present application.

FIG. 8 is a diagram showing the optimization algorithm of the present application.

FIG. 9 is a diagram showing the optimization algorithm of the present application.

FIG. 10 is a block diagram showing a configuration of a variable optimization system 10.

FIG. 11 is a block diagram showing a configuration of a node 100.

FIG. 12 is a flowchart showing an operation of the node 100.

FIG. 13 is a block diagram showing a configuration of a variable optimization unit 120 according to a first embodiment.

FIG. 14 is a flowchart showing an operation of the variable optimization unit 120 according to the first embodiment.

FIG. 15 is a block diagram showing a configuration of a variable optimization unit 120 according to a second embodiment.

FIG. 16 is a flowchart showing an operation of the variable optimization unit 120 according to the second embodiment.

FIG. 17 is a diagram showing an example of a functional configuration of a computer that realizes each device according to the embodiment of the present invention.

### DESCRIPTION OF EMBODIMENTS

The following describes an embodiment of the present invention in detail. Note that constituent units having the same function are denoted with the same number, and overlapping descriptions thereof are omitted.

A notation method used in this specification will be described before each embodiment is described.

A “\hat{ }” (caret) indicates a superscript. For example, x^{y\hat{ }z} indicates that y^{z} is a superscript to x, and x_{y\hat{ }z} indicates that y^{z} is a subscript to x. In addition, _(underscore) indicates a subscript. For example, x^{y_z} indicates that y_{z} is a superscript to x, and x_{y_z} indicates that y_{z} is a subscript to x.

Superscripts “\hat{ }” and “˜” for a certain letter x, as in “\hat{ }x” and “˜x”, should originally be written directly above “x”, but are written as “\hat{ }x” and “˜x” due to the restrictions of the descriptive notation of the specification.

### TECHNICAL BACKGROUND

### [1: ECL Algorithm]

As a method for solving the optimization problem, there are methods using a primal-dual form update rule in addition to the average consensus building and the stochastic variance reduced gradient method. As an example of a method using the primal-dual form update rule, for example, PDMM, Edge-Consensus Learning (ECL) are available. Here, the ECL will be described with reference to reference NPL 1.
(Reference NPL 1: K. Niwa, N. Harada, G. Zhang, and W. B. Kleijn, Edge-consensus learning: Deep learning on P2P networks with nonhomogeneous data. In Proceedings of the 26th ACM SIGKDD International Conference on Knowledge Discovery & Data Mining, pp. 668-678, 2020.)

The optimized model variables conform to the sum of learning data sets in all nodes as much as possible, and it is preferable that a consensus regarding the model variables is taken between the nodes. That is, the model variables are learned so as to reduce the cost function, and the model variables are learned so as to be substantially coincident with each other. Therefore, the optimization problem to be solved with respect to the model variables can be formulated as a cost minimization problem with a linear constraint such as the following expression.

$$Inf f ( w ) s . t . {A}_{i \vert j} {w}_{i} + {A}_{j \vert i} {w}_{j} = 0 ( {∀}_{i} ∈ N , {∀}_{j} ∈ {ε}_{i} ) … ( 2 ) \qquad [ Math . 27 ]$$

$${A}_{i \vert j} = \{ \begin{matrix}I ( i > j , j ∈ {ε}_{i} ) \\ - I ( i < j , j ∈ {ε}_{i} )\end{matrix} … ( 3 ) \qquad [ Math . 28 ]$$

Note that a sign of an identity matrix A_{i|j} of the expression (3) may be expressed as sign (A_{i|j}).

When the cost function f is a differentiable non-convex function, the following optimization problem in which the cost function f of the expression (2) is replaced by an upper bound function q in a quadratic form may be solved instead of solving the optimization problem of the expression (2).

$${inf}_{w} q ( w ) s . t . {A}_{i \vert j} {w}_{i} + {A}_{j \vert i} {w}_{j} = 0 ( {∀}_{i} ∈ N , {∀}_{j} ∈ {ε}_{i} ) … ( 4 ) \qquad [ Math . 29 ]$$

$$q ( w ) = \frac{1}{n} {\sum }_{i = 1}^{n} {q}_{i} ( {w}_{i} ) \qquad [ Math . 30 ]$$

$${q}_{i} ( {w}_{i} ) = {f}_{i} ( {w}_{i}^{r , k} ) + 〈 {g}_{i} ( {w}_{i}^{r , k} ) , {w}_{i} - {w}_{i}^{r , k} 〉 + \frac{1}{2 μ} {‖ {w}_{i} - {w}_{i}^{r , k} ‖}^{2} \qquad [ Math . 31 ]$$

Here, μ is a step size, and in the case of deep learning, it is set to a sufficiently small value such as 0.001. Further, wᵢ^{r,k} represent a value of the model variable wᵢ in the k-th update processing in the r-th round.

Solving a dual problem instead of solving the optimization problem of the expression (4) will be considered.

Specifically, a dual variable is defined as λ=[λ₁^{T}, . . . , λₙ^{T}]^{T} (where λᵢ=[λ_{i|ε_i(i)}^{T}, . . . , λ_{i|ε_i(E_i)}^{T}]^{T} is satisfied, and λ_{i|j}=λ_{j|i} for arbitrary i and j), and the dual problem related to the dual variable λ of the following expression is solved.

$${inf}_{λ} q * ( {J}^{T} {A}^{T} λ ) + {l}_{ker ( I - P )} ( λ ) … ( 5 ) \qquad [ Math . 32 ]$$

$$where ,$$

$$q * ( {J}^{T} {A}^{T} λ ) = {sup}_{w} 〈 λ , AJw 〉 - q ( w ) \qquad [ Math . 33 ]$$

$${l}_{ker ( I - P )} ( λ ) = \{ \begin{matrix}0 & ( ( I - P ) λ = 0 ) \\ + ∞ & ( otherwise )\end{matrix} \qquad [ Math . 34 ]$$

$$A = BlockDiag \{ [ {A}_{1} , … , {A}_{n} ] \} \qquad [ Math . 35 ]$$

$$A = BlockDiag \{ [ {A}_{i \vert {ε}_{i} ( 1 )} , … , {A}_{i \vert {ε}_{i} ( {E}_{i} )} ] \} \qquad [ Math . 36 ]$$

$$J = BlockDiag \{ [ {J}_{1} , … , {J}_{n} ] \} \qquad [ Math . 37 ]$$

$${J}_{i} = {[ I , … , I ]}^{T} \qquad [ Math . 38 ]$$

are established, and P is a matrix for replacing dual variables (hereinafter referred to as a permutation matrix) as follows.

$${λ}_{j \vert i} ↔ {λ}_{i \vert j} ( ∀ j ∈ {ε}_{i} ) \qquad [ Math . 39 ]$$

All the elements of the permutation matrix P are 0 or 1, and PP=I is satisfied.

Note that q* represents the convex conjugate function of the function q, and L_{ker(I-P)} represents an indicator function.

It is considered to derive a variable update rule for solving the optimization problem of expression (5). The dual variable λ satisfying the expression (5) is obtained when a subdifferential of the cost function q*(J^{T}A^{T}λ)+ι_{ker(I-P)} (λ) includes 0.

$$0 ∈ {T}_{1} ( λ ) + {T}_{2} ( λ ) … ( 6 ) \qquad [ Math . 40 ]$$

$${T}_{1} ( λ ) = AJ ∇ q * ( {J}^{T} {A}^{T} λ ) \qquad [ Math . 41 ]$$

$${T}_{2} ( λ ) = {\partial }_{ker ( I - P )} ( λ ) \qquad [ Math . 42 ]$$

When the dual variables y and z of the same dimension as the dual variable λ are introduced and the expression (6) is transformed by using monotone operator splitting, the following variable update rule can be obtained.

$${w}^{r , k + 1} = {argmin}_{w} ( q ( w ) + \frac{η}{2} ‖ AJw - {z}^{r . k} ‖ + \frac{ρ}{2} {‖ Jw - {PJw}^{r , k} ‖}^{2} ) … ( 7 ) \qquad [ Math . 43 ]$$

$${y}^{r , k + 1} = {z}^{r , k} - 2 {AJw}^{r , k + 1} … ( 8 ) \qquad [ Math . 44 ]$$

$${Z}^{r , k + 1} = \{ \begin{matrix}{Py}^{r , k + 1} ( PDMM - SGD ) \\ \frac{1}{2} {Py}^{r , k + 1} + \frac{1}{2} {Z}^{r , k} ( ADMM - SGD )\end{matrix} … ( 9 ) \qquad [ Math . 45 ]$$

The expression (7) is the update rule of the model variable w, expression (8) is the update rule of the dual variable y, and expression (9) is the update rule of the dual variable z. Also, the PDMM-SGD of expression (9) is the variable update rule obtained based on Peaceman-Rachford (P-R) type monotone operator splitting (PRS), and the ADMM-SGD is the variable update rule obtained based on Douglas-Rachford (D-R) type monotone operator splitting (DRS).

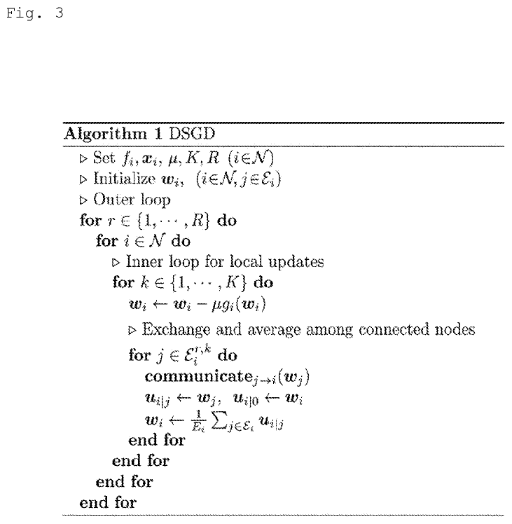

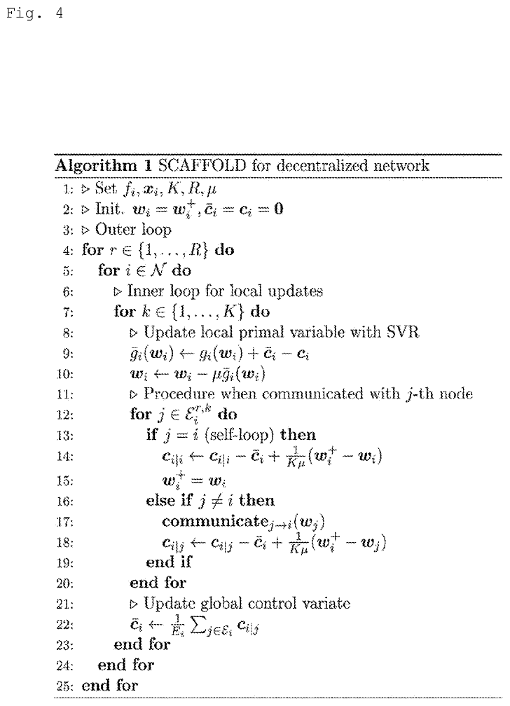

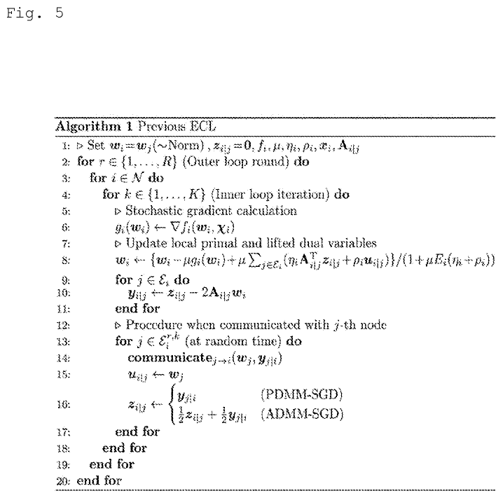

When the variable update rules of expression (7), (8) and (9) are split into the variable update rules for each node, an algorithm shown in FIG. 5 is obtained. This algorithm is the ECL algorithm. Here, qi is a constant representing a step size in the i-th node, and pi is a constant representing intensity of a regularization term in the i-th node. Similar to the algorithms shown in FIGS. 3 and 4, in the algorithm shown in FIG. 5 learning also advances by repeating the variable update processing in the node and the data exchange processing between the nodes. Both the variable update rule of the expression (7) and the variable update rule of the expression (8) are update rules in the variable update processing in the node. On the other hand, the variable update rule of the equation (9) is an update rule in data exchange processing between nodes, and in the PDMM-SGD, after the value of the model variable wⱼ and the value of the dual variable y_{j|i} are received from the j-th node, the value of the dual variable z_{i|j} is updated. On the other hand, in the ADMM-SGD, after receiving the value of the model variable wⱼ and the value of the dual variable y_{j|i} from the j-th node, the value of the dual variable z_{i|j} is averaged by using the value of the dual variable y_{j|i}, and the value of the dual variable z_{i|j} is updated.

### [2: Improvement of ECL Algorithm]

Since the update rule of the primal-dual form such as ECL minimizes the cost function while restricting the model of each node to be equivalent, resistant is strong against (1) the case where there is a statistical deviation in the accumulated learning data set and (2) the case where communication between nodes is asynchronous and sparse, similarly to the stochastic variance reduced gradient method. However, if the step size q and the intensity p of the regularization term are not appropriately selected, the learning may not converge well. In fact, the ECL has a problem that the values of q and p are empirically determined, so that the learning cannot be stably advanced.

Therefore, in order to stably advance learning by ECL, the following method is used.
(1) A control variable used in the stochastic variance reduced gradient method for reducing the variance of the stochastic gradient is introduced.
(2) A mini-batch is generated in the form of taking class balance into consideration.
(3) Normalization is performed in accordance with the number of data accumulated in the node.

The above three methods can be introduced into the ECL independently or in combination of two or more.

### [[Method (1)]]

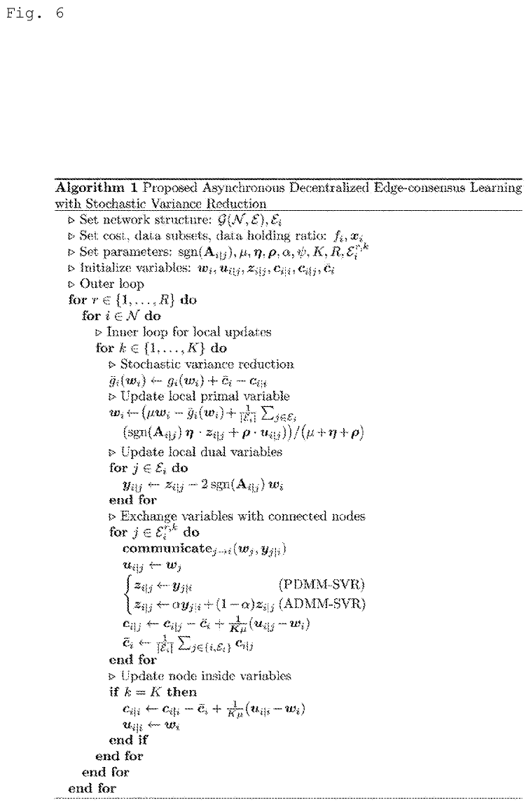

FIG. 6 shows an algorithm in which a method (1) is introduced into the ECL. In the algorithm shown in FIG. 6, the stochastic gradient gᵢ is corrected by using the expression (1) as in the stochastic variance reduced gradient method.

$${\overline{g}}_{i} ( {w}_{i} ) ← {g}_{i} ( {w}_{i} ) + {\overline{c}}_{i} - {c}_{i \vert i} \qquad [ Math . 46 ]$$

Note that, here, the local control variable is defined as c_{i|i}.

In addition, the value of the global control variable ⁻cᵢ is updated by the following expression.

$${c}_{i \vert j} ← {c}_{i \vert j} - {\overline{c}}_{i} + \frac{1}{K μ} ( {u}_{i \vert j} - {w}_{i} ) \qquad [ Math . 47 ]$$

$${\overline{c}}_{i} ← \frac{1}{\vert {ε}_{i} \vert} {\sum }_{j ∈ \{ i , {ε}_{i} \}} {c}_{i \vert j} \qquad [ Math . 48 ]$$

This expression indicates that the value of the global control variable is updated by using the value of the variable received from the node connected to the i-th node. Note that {i, εᵢ} represents a sum set of the set {i} and the set εᵢ. In addition, |εᵢ| represents the number of elements of the set εᵢ, that is, the concentration of the set εᵢ.

Further, the value of the local control variable c_{i|i} is updated by the following expression.

$${c}_{i \vert i} ← {c}_{i \vert i} - {\overline{c}}_{i} + \frac{1}{K μ} ( {u}_{i \vert i} - {w}_{i} ) \qquad [ Math . 49 ]$$

This equation indicates that the value of the local control variable c_{i|i} is updated by using the value of the variable of its own node.

### [[Method (2)]]

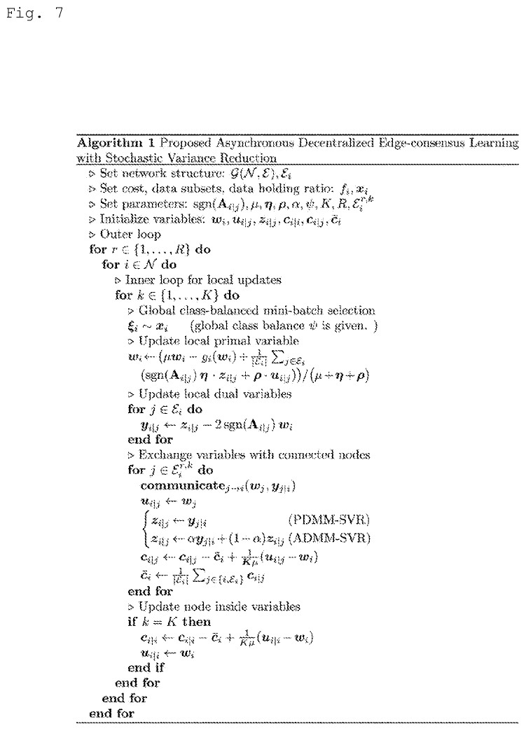

FIG. 7 shows an algorithm in which the method (2) is introduced into the ECL. It is assumed that a distribution ψ for each type (class) of learning data accumulated in N nodes, that is, a distribution ψrepresenting class balance is known in advance. The learning data is selected from the learning data set xᵢ accumulated in the i-th node in accordance with the distribution ψ, and a mini-batch i is generated.

$${ξ}_{i} ∼ {x}_{i} \qquad [ Math . 50 ]$$

The value of the stochastic gradient gᵢ is calculated by using the mini-batch εᵢ.

### Method (3)

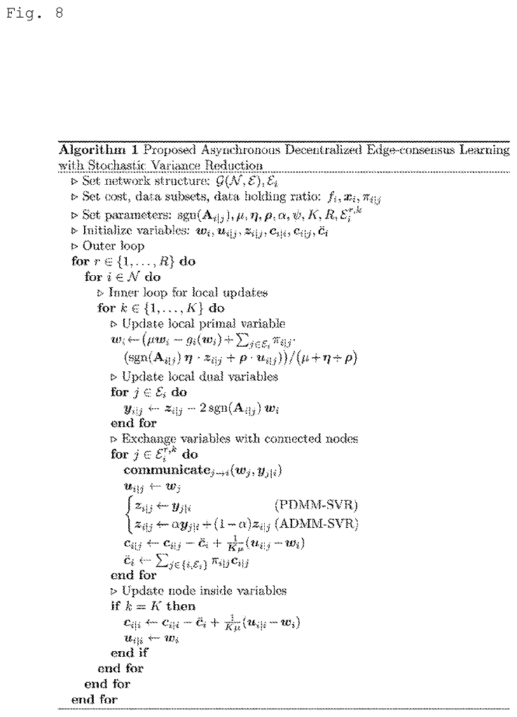

FIG. 8 shows an algorithm in which a method (3) is introduced into the ECL. When the number of data dᵢ of the learning data set xᵢ is known in advance, the ratio π_{i|j} occupied by the number of data accumulated in the j-th node connected to the I-th node with respect to the number of data accumulated in all nodes connected to the i-th node and the i-th node is calculated by the following expression.

$${π}_{i \vert j} = \frac{{d}_{j}}{{\sum }_{j ∈ \{ i , {E}_{i} \}} {d}_{j}} \qquad [ Math . 51 ]$$

The ratio π_{i|j} is used as a weight β_{i|j} in the i-th node corresponding to the j-th node, and the value of the model variable wᵢ is updated. That is, in the ECL, the value of the model variable wᵢ is updated by simple averaging without weighting, but in the method (3), the value of the model variable wᵢ is updated by performing weighting by using π_{i|j} and averaging. Further, when the method (3) is used in combination with the method (1), the value of the global control variable ⁻cᵢ is also updated by using π_{i|j}.

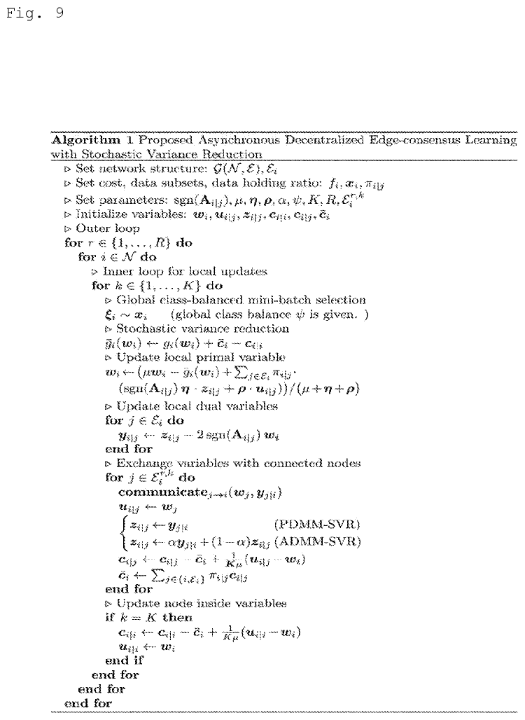

As described above, two or more methods among the method (1) to (3) can be combined. As an example of the combination, FIG. 9 shows an algorithm in which methods (1) to (3) are introduced into the ECL.

By introducing the methods (1) to (3) appropriately into the ECL, it was confirmed by numerical experiments that the learning can be stably performed without being affected by the difference in the number of elements and statistical properties of the learning data set accumulated in each node compared with the ECL. Among them, it was experimentally confirmed that the effects of the methods (1) and (2) were particularly high.

### First Embodiment

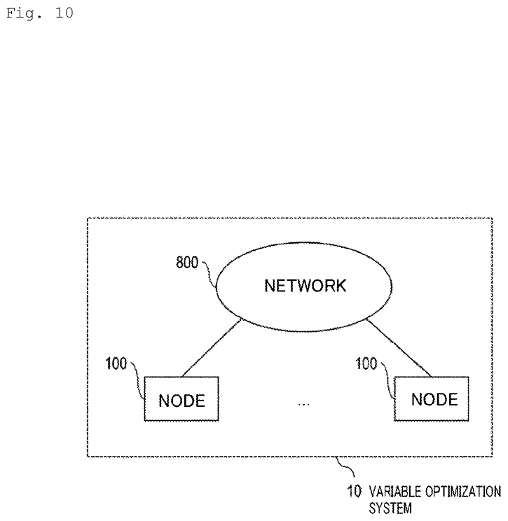

The variable optimization system 10 will be described below with reference to FIGS. 10 to 12. FIG. 10 is a block diagram showing a configuration of the variable optimization system 10. The variable optimization system 10 is constituted by n (n is an integer of 2 or more) nodes. Each node is connected to a network 800. The network 800 may be, for example, the Internet. However, it is assumed that a node connected to and communicating with the node is predetermined for each node. In addition, each node accumulates a set of learning data (hereinafter referred to as a learning data set) used for optimizing model variables.

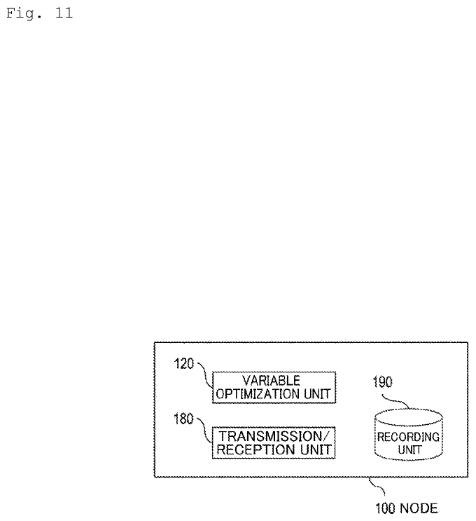

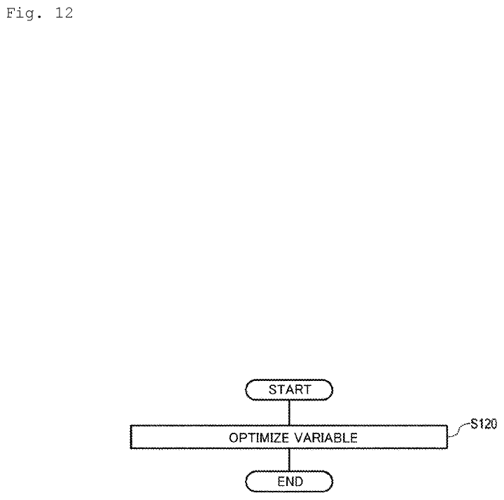

FIG. 11 is a block diagram showing a configuration of a node 100. FIG. 12 is a flowchart showing an operation of the node 100. As shown in FIG. 11, the node 100 includes a variable optimization unit 120, a transmission/reception unit 180, and a recording unit 190. The transmission/reception unit 180 is a constituent unit for appropriately transmitting/receiving data that needs to be exchanged with another node. The recording unit 190 is a constituent unit for appropriately recording information necessary for processing of the node 100. Learning data set, for example, is recorded in the recording unit 190.

N={1, . . . , n} is defined as an index set of nodes, i∈N. wᵢ is a model variable in the i-th node, xᵢ is a learning data set in the i-th node, fᵢ(wᵢ) is a cost function in the i-th node, and εᵢ is an index set of nodes to which the i-th node is connected. ⁻cᵢ is a global control variable in the i-th node, and c_{i|i} is a local control variable in the i-th node. yᵢ|j and z_{i|j}(j∈εᵢ) are dual variables in the i-th node corresponding to the j-th node, respectively, and A_{i|j}(j∈εᵢ) is a parameter matrix defined by the following expression.

$${A}_{i \vert j} = \{ \begin{matrix}I ( i > j ) \\ - I ( i < j )\end{matrix} \qquad [ Math . 52 ]$$

R, K are integers of 1 or more, respectively, {1, 2, . . . , R} is a set representing the number of times of execution of the round, {1, 2, . . . , K} is a set representing the number of times of execution of the update processing, and εᵢ^{r,k}(r∈{1, 2, R}, k∈{1, 2, . . . , K}) is an index set of nodes to be communicated of the i-th node in the k-th update processing in the r-th round. Hereinafter, r is referred to as a round execution number counter, and k is referred to as an update processing execution number counter. Note that r and k are simply referred to as counters.

An operation of the node 100 will be described in accordance with FIG. 12.

In S120, the variable optimization unit 120 optimizes the model variable wᵢ to be optimized by a predetermined procedure by using the learning data set xᵢ, and outputs a result as an output value. At that time, the variable optimization unit 120 appropriately receives predetermined data from the j-th node (where j satisfies j∈εᵢ) by using the transmission/reception unit 180, and optimizes the model variable wᵢ. Note that the data received by the i-th node from the j-th node will be described later.

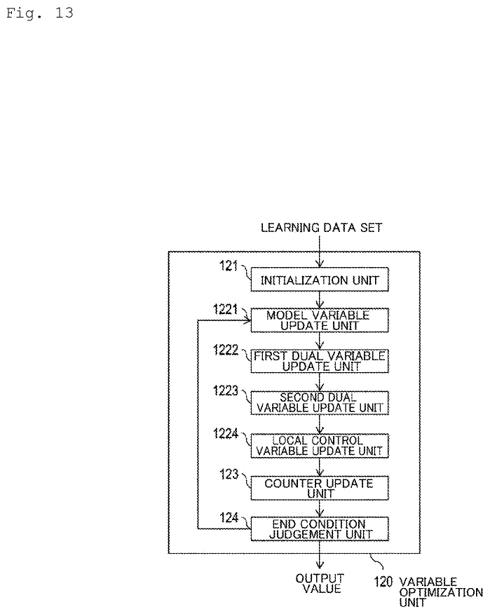

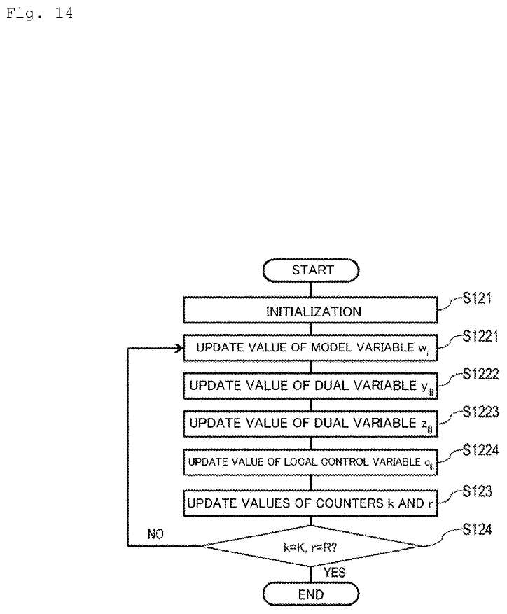

Hereinafter, the variable optimization unit 120 will be described with reference to FIGS. 13 and 14. FIG. 13 is a block diagram showing a configuration of the variable optimization unit 120. FIG. 14 is a flowchart illustrating an operation of the variable optimization unit 120. As shown in FIG. 13, the variable optimization unit 120 includes an initialization unit 121, a model variable update unit 1221, a first dual variable update unit 1222, a second dual variable update unit 1223, a local control variable update unit 1224, a counter update unit 123, and an end condition judgement unit 124.

The operation of the variable optimization unit 120 of the i-th node will be described in accordance with FIG. 14.

In S121, the initialization unit 121 performs initialization processing required for optimizing the model variable wᵢ. The contents of initialization processing will be described below. The initialization unit 121 initializes counters r and k. The initialization unit 121 initializes the counter r by setting r←1. Similarly, the initialization unit 121 initializes the counter k by setting k←1. In addition, the initialization unit 121 initializes the model variable wᵢ, the temporary variable u_{i|j} and the dual variable z_{i|j} (j∈εᵢ) in the i-th node corresponding to the j-th node. The initialization unit 121 uses, for example, a random number to set an initial value of the model variable wᵢ, an initial value of the temporary variable u_{i|j}, and an initial value of the dual variable z_{i|j}. Further, the initialization unit 121 initializes the global control variable ⁻cᵢ, the local control variable ciii, and the local control variable c_{i|j} in the i-th node corresponding to the j-th node. The initialization unit 121 uses, for example, a random number to set an initial value of the global control variable ⁻cᵢ, an initial value of the local control variable ciii, and an initial value of the local control variable c_{i|j}.

In S1221, the model variable update unit 1221 updates the value of the model variable wᵢ by the following expression.

$${g}_{i} ( {w}_{i} ) ← ∇ {f}_{i} ( {w}_{i} ) \qquad [ Math . 53 ]$$

(where, ∇fᵢ(wᵢ) is calculated using a mini-batch x_{i,MB} which is a subset of the learning data set xᵢ)

$${\overline{g}}_{i} ( {w}_{i} ) ← {g}_{i} ( {w}_{i} ) + {\overline{c}}_{i} - {c}_{i \vert i} \qquad [ Math . 54 ]$$

$${w}_{i} ← \frac{( µ {w}_{i} - {\overline{g}}_{i} ( {w}_{i} ) + {\sum }_{j ∈ {ε}_{i}} {β}_{i \vert j} ( sgn ( {A}_{i \vert j} ) η \cdot {z}_{i \vert j} + ρ \cdot {u}_{i \vert j} ) )}{( µ + η + ρ )} \qquad [ Math . 55 ]$$

(where μ, η and ρ are predetermined vectors, β_{i|j} is a weight in the i-th node corresponding to the j-th node, and sign (A_{i|j}) represents the sign of the identity matrix A_{i|j}) The vectors p, q and p may be set by the initialization unit 121 in S121, for example.

Also, when the distribution ψ (that is, the ratio of each class), which is the type of learning data accumulated in the N nodes, is known in advance, a mini-batch generated from the learning data set xᵢ in accordance with the distribution ψ can be used as the mini-batch x_{i,MB}.

The weight β_{i|j} may be set by the initialization unit 121 in S121, for example. For example, β_{i|j}=1/|εᵢ| may be simply set. In addition, when the number of data dᵢ of the learning data set xᵢ is known in advance, the weight β_{i|j} may be the ratio π_{i|j} occupied by the number of data accumulated in the j-th node connected to the i-th node with respect to the number of data accumulated in all nodes connected to the i-th node and the i-th node is calculated by the following expression.

$${π}_{i \vert j} = \frac{{d}_{j}}{{\sum }_{j ∈ \{ i , {ε}_{i} \}} {d}_{j}} \qquad [ Math . 56 ]$$

In S1222, the first dual variable update unit 1222 updates a value of dual variable y_{i|j} with respect to the index j satisfying j∈εᵢ by the following expression.

$${y}_{i \vert j} ← {z}_{i \vert j} - 2 sgn ( {A}_{i \vert j} ) {w}_{i} \qquad [ Math . 57 ]$$

In S1223, the second dual variable update unit 1223 receives a value of the model variable wⱼ and a value of dual variable y_{j|i} with respect to the index j satisfying j∈εᵢ^{r,k} form the j-th node, and update a value of dual variable z_{i|j} by the following expression, and updates a value of the global control variable ⁻cᵢ by the following expression.

$${u}_{i \vert j} ← {w}_{j} \qquad [ Math . 58 ]$$

$${c}_{i \vert j} ← {c}_{i \vert j} - {\overline{c}}_{i} + \frac{1}{K μ} ( {u}_{i \vert j} - {w}_{i} ) \qquad [ Math . 59 ]$$

$${\overline{c}}_{i} ← {\sum }_{j ∈ \{ i , {ε}_{i} \}} {β}_{i \vert j} {c}_{i \vert j} \qquad [ Math . 60 ]$$

Here, the expression used by the second dual variable update unit 1223 for updating a value of the dual variable z_{i|j} is

$${z}_{i \vert j} ← {y}_{j \vert i} \qquad [ Math . 61 ]$$

$$or$$

$${z}_{i \vert j} ← α {y}_{j \vert i} + ( 1 - α ) {z}_{i \vert j} \qquad [ Math . 62 ]$$

(where α is a predetermined constant satisfying 0<α<1)

The constant α may be set by the initialization unit 121 in S121, for example.

In S1224, when execution of update processing in the r-th round is the K-th (that is, when a counter k satisfies k=K) the local control variable update unit 1224 updates, by the following expressions, a value of the local control variable c_{i|i}, and a value of the temporary variable u_{i|i} in the i-th node.

$${c}_{i \vert i} ← {c}_{i \vert i} - {\overline{c}}_{i} + \frac{1}{K μ} ( {u}_{i \vert i} - {w}_{i} ) \qquad [ Math . 63 ]$$

$${u}_{i \vert i} ← {w}_{i} \qquad [ Math . 64 ]$$

In S123, when the counter k satisfies k=K, the counter update unit 123 initializes the counter k (that is, k←1 is set), and increment the counter r by 1 (that is, r←r+1 is set), and on the other hands, in other cases, the counter k is incremented by 1 (that is, k←k+1 is set).

In S124, when the counter r has reached a predetermined update count R (that is, the counter r satisfies r=R), the end condition judgement unit 124 outputs a value of the model wᵢ at that time as an output value and ends the processing, and on the other hands, in other cases, the processing returns to S1221. That is, the variable optimization unit 120 outputs a value of the variable wᵢ at that time when a predetermined termination condition is satisfied, and in other cases, the processing of S1221 to S124 is repeated.

According to an embodiment of the present invention, even when there is the statistical deviation in the learning data set distributed and accumulated in the plurality of nodes, or communication between nodes is asynchronous and sparse, the model variable can be stably optimized so as to conform to the learning data set.

### Second Embodiment

In the first embodiment, the variable optimization unit 120 updates the model variable using the value obtained by adding the difference between the two control variables to the stochastic gradient, but the variable optimization unit 120 may update the model variable simply using the value of the stochastic gradient. Such an embodiment will be described below. The first embodiment and the second embodiment are different from each other only in a configuration and operation of the variable optimization unit 120.

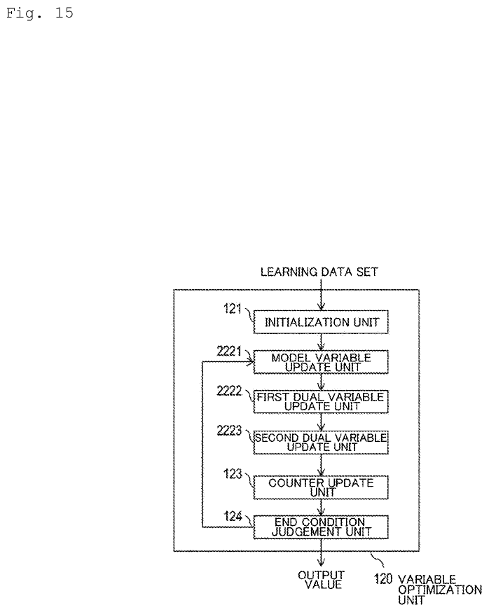

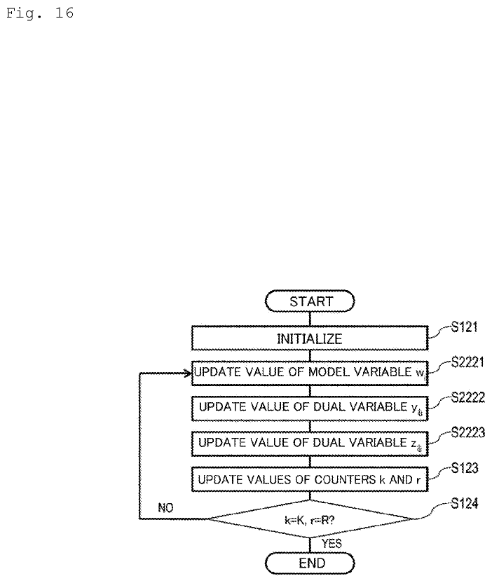

Hereinafter, the variable optimization unit 120 will be described with reference to FIGS. 15 and 16. FIG. 15 is a block diagram showing a configuration of the variable optimization unit 120. FIG. 16 is a flowchart showing an operation of the variable optimization unit 120. As shown in FIG. 15, the variable optimization unit 120 includes an initialization unit 121, a model variable update unit 2221, a first dual variable update unit 2222, a second dual variable update unit 2223, a counter update unit 123, and an end condition judgement unit 124.

An operation of the variable optimization unit 120 of the i-th node will be described in accordance with FIG. 16.

In S121, the initialization unit 121 performs initialization processing required for optimizing the model variable wᵢ. The initialization unit 121 initializes counters r and k. In addition, the initialization unit 121 initializes the model variable wᵢ, the temporary variable u_{i|j} and the dual variable z_{i|j}(j∈εᵢ) in the i-th node corresponding to the j-th node.

In S2221, the model variable update unit 2221 updates the model variable wᵢ by the following expression.

$${g}_{i} ( {w}_{i} ) ← ∇ {f}_{i} ( {w}_{i} ) \qquad [ Math . 65 ]$$

(where, ∇fᵢ(wᵢ) is calculated using a mini-batch x_{i,MB} which is a subset of the learning data set xᵢ.)

$${w}_{i} ← \frac{( μ {w}_{i} - {g}_{i} ( {w}_{i} ) + {\sum }_{j ∈ {ε}_{i}} {β}_{i \vert j} ( sgn ( {A}_{i \vert j} ) η \cdot {Z}_{i \vert j} + ρ \cdot {u}_{i \vert j} ) )}{( μ + η + ρ )} \qquad [ Math . 66 ]$$

(where μ, η and ρ are predetermined vectors, β_{i|j} is a weight in the I-th node corresponding to the j-th node, and sign (A_{i|j}) represents the sign of the identity matrix A_{i|j}). The vectors μ, η and ρ may be set by an initialization unit 121 in S121, for example.

Also, when the distribution ψ (that is, the ratio of each class), which is the kind of learning data accumulated in the N nodes, is known in advance, a mini-batch generated from the learning data set xᵢ in accordance with the distribution ψ can be used as a mini-batch x_{i,MB}.

The weight β_{i|j} may be set by the initialization unit 121 in S121, for example. For example, β_{i|j}=1/|εᵢ| may be set. In addition, when the number of data dᵢ of the learning data set xᵢ is known in advance, the weight β_{i|j} may be the ratio π_{i|j} occupied by the number of data accumulated in the j-th node connected to the i-th node with respect to the number of data accumulated in all nodes connected to the i-th node and the i-th node is calculated by the following expression.

$${π}_{i \vert j} = \frac{{d}_{j}}{{\sum }_{j ∈ \{ i , {ε}_{i} \}} {d}_{j}} \qquad [ Math . 67 ]$$

In S2222, the first dual variable update unit 2222 updates a value of the dual variable y_{i|j} with respect to the index j satisfying j∈εᵢ by the following expression.

$${y}_{i \vert j} ← {z}_{i \vert j} - 2 sgn ( {A}_{i \vert j} ) {w}_{i} \qquad [ Math . 68 ]$$

In S2223, the second dual variable update unit 2223 receives a value of the model variable wⱼ and a value of the dual variable y_{j|i} with respect to the index j satisfying j∈εᵢ^{r,k} from the j-th node, update a value of the dual variable z_{i|j} by a predetermined expression, and update a value of the temporary variable u_{i|j} by the following expression.

$${u}_{i \vert j} ← {w}_{j} \qquad [ Math . 69 ]$$

Here, the expression used by the second dual variable update unit 2223 for updating a value of the dual variable z_{i|j} is

$${z}_{i \vert j} ← {y}_{j \vert i} \qquad [ Math . 70 ]$$

$${z}_{i \vert j} ← α {y}_{j \vert i} + ( 1 - α ) {z}_{i \vert j} \qquad [ Math . 71 ]$$

(where α is a predetermined constant satisfying 0<α<1)

The constant α may be set by the initialization unit 121 in S121, for example.

In S123, when the counter k satisfies k=K, the counter update unit 123 initializes the counter k (that is, k←1 is set), and increments the counter r by 1 (that is, r←r+1 is set), and on the other hands, in other cases, the counter k is incremented by 1 (that is, k←k+1 is set).

In S124, when the counter r has reached a predetermined update count R (that is, the counter r satisfies r=R), the end condition judgement unit 124 outputs a value of the model variable wᵢ at that time as an output value, and end the processing, on the other hands, in other cases, the processing returns to S2221. That is, the variable optimization unit 120 outputs a value of the variable wᵢ at that time when a predetermined end condition is satisfied, and in other cases, the processing of S2221 to S124 is repeated.

According to the embodiment of the present invention, even when there is the statistical deviation in the learning data set distributed and accumulated in the plurality of nodes, or communication between nodes is asynchronous and sparse, it is possible to stably optimize the variable of model so as to comfort to the learning data set.

### APPLICATION EXAMPLE

Here, examples to which each embodiment of the present invention can be applied will be described.

### Example 1: V2X (Vehicle to Everything)

In an environment in which as represented by a connected car an automobile and an automobile, or an infrastructure, etc. are connected to each other, the automobile and the infrastructure are regarded as nodes in each embodiment. Information from various sensors mounted on the automobile or the infrastructure, such as an image, an acoustic signal, an acceleration is accumulated in each node. Each embodiment of the present invention may be used when the accumulated data is used as learning data and one cost function is optimized. In this case, the cost function can be designed by using an index corresponding to the purpose such that, for example, the arrival time is minimized, the total amount of energy used is minimized, and the physical distance between nodes is made equal to or greater than a certain value.

### Example 2: Digital Twin

In a situation where a plurality of digital twins affects each other, the digital twins are regarded as nodes in each embodiment. Learning data are accumulated in a form of being distributed to each digital twin. Each embodiment of the present invention may be used when one cost function is optimized without sharing the accumulated learning data with other nodes. For example, when the food loss is to be solved by using digital twin, individual persons and individual stores can be configured as digital twin, and a cost function having a cost term for minimizing the food amount of all stores can be used. Further, by using index values expressing the individual happiness, a cost function may be designed to minimize the food amount in all stores while maximizing the total sum of the index values.

### SUPPLEMENTARY NOTE

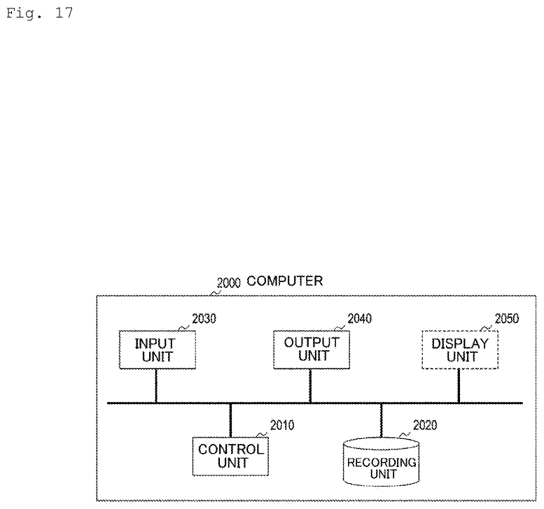

FIG. 17 is a diagram showing an example of a functional configuration of a computer that realizes each of the above-mentioned devices (i.e., each node). Processing performed in each device described above can be implemented by causing a recording unit 2020 to read a program for causing the computer to function as each device described above, and causing a control unit 2010, an input unit 2030, an output unit 2040, and the like to operate.

The device of the present invention includes, for example, as a single hardware entity, an input unit to which a keyboard or the like can be connected, an output unit to which a liquid crystal display or the like can be connected, a communication unit to which a communication device (for example, a communication cable) capable of communicating with the outside of the hardware entity can be connected, a central processing unit (CPU; which may also include a cache memory, registers, etc.), a RAM or ROM which is a memory, an external storage device which is a hard disk, and a bus that connects the input unit, the output unit, the communication unit, the CPU, the RAM, the ROM, and the external storage device such that data can be exchanged therebetween. Also, as necessary, the hardware entity may be provided with a device (drive) capable of reading and writing a recording medium such as a CD-ROM. A general-purpose computer or the like is an example of a physical entity including such hardware resources.

The external storage device of the hardware entity stores a program that is needed to realize the above-mentioned functions and data needed for the processing of this program (not limited to the external storage device, and for example, the program may also be stored in a ROM, which is a read-only storage device). Also, the data and the like obtained through the processing of these programs is appropriately stored in a RAM, an external storage device, or the like.

In the hardware entity, each program stored in the external storage device (or the ROM, etc.) and the data needed for processing of each program are loaded to the memory as needed, and the CPU interprets, executes, and processes them as appropriate. As a result, the CPU realizes a predetermined function (each constituent unit represented by the above, unit, . . . means, etc.).

The present invention is not limited to the above-described embodiment, and appropriate changes can be made without departing from the spirit of the present invention. Further, the processing described in the embodiments are not only executed in time series in the described order, but also may be executed in parallel or individually according to a processing capability of a device that executes the processing or as necessary.

As described above, when the processing function in the hardware entity (device of the present invention) described in the above-described embodiments is realized by the computer, the processing contents of the function to be included in the hardware entity are described by the program. Then, by executing this program on the computer, the processing function in the above-described hardware entity is realized on the computer.

The program describing the processing contents can be recorded in a computer-readable recording medium. Any computer-readable recording medium may be used, such as a magnetic recording device, an optical disc, a magneto-optical recording medium, or a semiconductor memory. Specifically, for example, a hard disk device, a flexible disk, a magnetic tape, or the like can be used as the magnetic recording device, a digital versatile disc (DVD), a DVD-random access memory (DVD-RAM), a compact disc read only memory (CD-ROM), CD-recordable/rewritable (CD-R/RW), or the like can be used as the optical disc, a magneto-optical disc (MO) or the like can be used as the magneto-optical recording medium, and an electronically erasable and programmable-read only memory (EEP-ROM) or the like can be used as the semiconductor memory.

In addition, the program is distributed, for example, by sales, transfer, or lending of a portable recording medium such as a DVD or a CD-ROM on which the program is recorded. Further, the distribution of the program may be performed by storing the program in advance in a storage device of a server computer and transferring the program from the server computer to another computer via a network.

The computer executing such a program first stores, for example, the program recorded on the portable recording medium or the program transferred from the server computer in its own storage device. When executing the processing, the computer reads the program stored in its own storage device, and executes the processing in accordance with the read program. As another execution form of the program, the computer may directly read the program from the portable recording medium and execute processing in accordance with the program, each time the program is transferred from the server computer to the computer, processing in accordance with the received program may be executed sequentially. In addition, by a so-called application server provider (ASP) type service which does not transfer the program from the server computer to the computer and realizes the processing function only by the execution instruction and the result acquisition, the above-mentioned processing may be executed. Note that it is assumed that the program in this form includes information to be used for processing by the computer and equivalent to the program (data that is not a direct command to the computer but has the property of defining the processing of the computer, etc.).

Further, although the hardware entity is configured by a predetermined program being executed on the computer in the present embodiment, at least a part of the processing contents of the hardware entity may be realized in hardware.

The above description of the embodiments of the present invention is presented for the purpose of illustration and description. There is no intention to be exhaustive and there is no intention to limit the invention to a disclosed exact form. Modifications or variations are possible from the above-described teachings. The embodiments are selectively represented in order to provide the best illustration of the principle of the present invention and in order for those skilled in the art to be able to use the present invention in various embodiments and with various modifications so that the present invention is suitable for deliberated practical use. All of such modifications or variations are within the scope of the present invention defined by the appended claims interpreted according to a width given fairly, legally and impartially.

1. A variable optimization system that constituted by n (n is an integer 2 or more) nodes and optimizes a model variable by using a learning data set that is a learning data set accumulated in each node, in which
N={1, . . . , n} is an index set of nodes, i∈N is set,
wᵢ is a model variable in the i-th node, xᵢ is a learning data set in the i-th node, fᵢ(wᵢ) is a cost function in the i-th node, εᵢ is an index set of nodes to which the i-th node is connected,
⁻cᵢ is a global control variable in the i-th node, c_{i|i} is a local control variable in the i-th node,
y_{i|j} and z_{i|j}(j∈εᵢ) are dual variables in the i-th node corresponding to the j-th node, respectively, A_{i|j}(j∈εᵢ) is a parameter matrix defined by the following expression,
$${A}_{i \vert j} = \{ \begin{matrix}I ( i > j ) \\ - I ( i < j )\end{matrix} \qquad [ Math . 72 ]$$
R and K are integers of 1 or more, respectively, {1, 2, . . . , R} is a set representing the number of times of execution of a round, {1, 2, . . . , K} is a set representing the number of times of execution of update processing, εᵢ^{r,k}(r∈{1, 2, . . . , R}, k∈{1, 2, . . . , K}) is an index set of nodes to be communicated by the i-th node in the k-th update processing in the r-th round,
the variable optimization system comprising a processor configured to execute operations comprising:
updating a value of the model variable wᵢ in the i-th node by the following expression;
$${g}_{i} ( {w}_{i} ) ← ∇ {f}_{i} ( {w}_{i} ) \qquad [ Math . 73 ]$$
(where, ∇fᵢ(wᵢ) is calculated using a mini-batch x_{i,MB} which is a subset of the learning data set xᵢ)
$${\overline{g}}_{i} ( {w}_{i} ) ← {g}_{i} ( {w}_{i} ) + {\overline{c}}_{i} - {c}_{i \vert i} \qquad [ Math . 74 ]$$
$${w}_{i} ← \frac{( μ {w}_{i} - {\overline{g}}_{i} ( {w}_{i} ) + {\sum }_{j ∈ {ε}_{i}} {β}_{i \vert j} ( sgn ( {A}_{i \vert j} ) η \cdot {Z}_{i \vert j} + ρ \cdot {u}_{i \vert j} ) )}{( μ + η + ρ )} \qquad [ Math . 75 ]$$
(where μ, η and ρ are predetermined vectors, β_{i|j} is a weight in the i-th node corresponding to the j-th node, u_{i|j} is a temporary variable in the i-th node corresponding to the j-th node, and sign (A_{i|j}) is a sign of an identity matrix A_{i|j});
updating a value of a dual variable y_{i|j} by the following expression for an index j satisfying j∈εᵢ
$${y}_{i \vert j} ← {z}_{i \vert j} - 2 sgn ( {A}_{i \vert j} ) {w}_{i} ; \qquad [ Math . 76 ]$$
receiving, for an index j satisfying j∈εᵢ^{r,k}, a value of the model variable wⱼ and a value of the dual variable y_{j|i} from the j-th node;
updating a value of the dual variable z_{i|j} by a predetermined expression;
updating a value of the global control variable ⁻cᵢ by the following expression:
$${u}_{i \vert j} ← {w}_{j} \qquad [ Math . 77 ]$$
$${c}_{i \vert j} ← {c}_{i \vert j} - {\overline{c}}_{i} + \frac{1}{K μ} ( {u}_{i \vert j} - {w}_{i} ) \qquad [ Math . 78 ]$$
$${\overline{c}}_{i \vert j} ← {\sum }_{j ∈ \{ i , {ε}_{i} \}} {β}_{i \vert j} {c}_{i \vert j} ; \qquad [ Math . 79 ]$$
and
updating a value of the local control variable c_{i|i} and a value of the temporary variable u_{i|i} in the i-th node by the following expression when the execution of the update processing is the K-th in the r-th round; and
$${c}_{i \vert i} ← {c}_{i \vert i} - {\overline{c}}_{i} + \frac{1}{K μ} ( {u}_{i \vert i} - {w}_{i} ) \qquad [ Math . 80 ]$$
$${u}_{i \vert i} ← {w}_{i} . \qquad [ Math . 81 ]$$

2. A variable optimization system that constituted by n (n is an integer 2 or more) nodes and optimizes a model variable by using a learning data set that is a learning data set accumulated in each node, in which
N={1, . . . , n} is an index set of nodes, i∈N is set,
wᵢ is a model variable in the i-th node, xᵢ is a learning data set in the i-th node, fᵢ(wᵢ) is a cost function in the i-th node, εᵢ is an index set of nodes to which the i-th node is connected,
y_{i|j} and z_{i|j}(j∈εᵢ) are dual variables in the i-th node corresponding to the j-th node, respectively, A_{i|j}(j∈εᵢ) is a parameter matrix defined by the following expression,
$${A}_{i \vert j} = \{ \begin{matrix}I ( i > j ) \\ - I ( i < j )\end{matrix} \qquad [ Math . 82 ]$$
R and K are integers of 1 or more, respectively, {1, 2, . . . , R} is a set representing the number of times of execution of a round, {1, 2, . . . , K} is a set representing the number of times of execution of update processing, εᵢ^{r,k}(r∈{1, 2, . . . , R}, k∈{1, 2, . . . , K}) is an index set of nodes to be communicated by the i-th node in the k-th update processing in the r-th round,
the variable optimization system comprising a processor configured to execute operations comprising:
updating a value of the model variable wᵢ in the i-th node by the following expression:
$${g}_{i} ( {w}_{i} ) ← ∇ {f}_{i} ( {w}_{i} ) \qquad [ Math . 83 ]$$
(where, ∇fᵢ(wᵢ) is calculated using a mini-batch x_{i,MB} which is a subset of the learning data set xᵢ)
$${w}_{i} ← \frac{( μ {w}_{i} - {g}_{i} ( {w}_{i} ) + {\sum }_{j ∈ {ε}_{i}} {β}_{i \vert j} ( sgn ( {A}_{i \vert j} ) η \cdot {z}_{i \vert j} + ρ \cdot {u}_{i \vert j} ) )}{( μ + η + ρ )} \qquad [ Math . 84 ]$$
(where, μ, η and ρ are predetermined vectors, β_{i|j} is a weight in the i-th node corresponding to the j-th node, u_{i|j} is a temporary variable in the i-th node corresponding to the j-th node, and sign (A_{i|j}) is a sign of an identity matrix A_{i|j});
updating a value of a dual variable y_{i|j} by the following expression for an index j satisfying j∈εᵢ
$${y}_{i \vert j} ← {z}_{i \vert j} - 2 sgn ( {A}_{i \vert j} ) {w}_{i} ; \qquad [ Math . 85 ]$$
receiving, for an index j satisfying j∈εᵢ^{r,k}, a value of the model variable wⱼ and a value of the dual variable y_{j|i} from the j-th node,
updating a value of the dual variable z_{i|j} by a predetermined expression; and
updating a value of the temporary variable u_{i|j} by the following expression
$${u}_{i \vert j} ← {w}_{j} , \qquad [ Math . 86 ]$$
wherein
ψ is a distribution for each type of learning data accumulated in the n nodes, and
a mini-batches x_{i,MB} is a mini-batch generated from the learning data set xᵢ in accordance with the distribution ψ.

3. A variable optimization system that constituted by n (n is an integer 2 or more) nodes and optimizes a model variable by using a learning data set that is a learning data set accumulated in each node, in which
N={1, . . . , n} is an index set of nodes, i∈N is set,
wᵢ is a model variable in the i-th node, xᵢ is a learning data set in the i-th node, fᵢ(wᵢ) is a cost function in the i-th node, εᵢ is an index set of nodes to which the i-th node is connected,
y_{i|j} and z_{i|j}(j∈εᵢ) are dual variables in the i-th node corresponding to the j-th node, respectively, A_{i|j}(j∈εᵢ) is a parameter matrix defined by the following expression,
$${A}_{i \vert j} = \{ \begin{matrix}I ( i > j ) \\ - I ( i < j )\end{matrix} \qquad [ Math . 87 ]$$
R and K are integers of 1 or more, respectively, {1, 2, . . . , R} is a set representing the number of times of execution of a round, {1, 2, . . . , K} is a set representing the number of times of execution of update processing, εᵢ^{r,k}(r∈{1, 2, . . . , R}, k∈{1, 2, . . . , K}) is an index set of nodes to be communicated by the i-th node in the k-th update processing in the r-th round,
the variable optimization system comprising a processor configured to execute operations comprising:
updating a value of the model variable wᵢ in the i-th node by the following expression:
$${g}_{i} ( {w}_{i} ) ← ∇ {f}_{i} ( {w}_{i} ) \qquad [ Math . 88 ]$$
(where, ∇fᵢ(wᵢ) is calculated using a mini-batch x_{i,MB} which is a subset of the learning data set xᵢ)
$${w}_{i} ← \frac{( μ {w}_{i} - {g}_{i} ( {w}_{i} ) + {\sum }_{j ∈ {ε}_{i}} {β}_{i \vert j} ( sgn ( {A}_{i \vert j} ) η \cdot {z}_{i \vert j} + ρ \cdot {u}_{i \vert j} ) )}{( μ + η + ρ )} \qquad [ Math . 89 ]$$
(where, μ, η and ρ are predetermined vectors, β_{i|j} is a weight in the i-th node corresponding to the j-th node, u_{i|j} is a temporary variable in the i-th node corresponding to the j-th node, and sign (A_{i|j}) is a sign of an identity matrix A_{i|j}),
updating a value of a dual variable y_{i|j} by the following expression for an index j satisfying j∈εᵢ
$${y}_{i \vert j} ← {z}_{i \vert j} - 2 sgn ( {A}_{i \vert j} ) {w}_{i} ; \qquad [ Math . 90 ]$$
receiving, for an index j satisfying j∈εᵢ^{r,k}, a value of the model variable wⱼ and a value of the dual variable y_{j|i} from the j-th node
updating a value of the dual variable z_{i|j} by a predetermined expression; and
updating a value of the temporary variable u_{i|j} by the following expression
$${u}_{i \vert j} ← {w}_{j} , \qquad [ Math . 91 ]$$
wherein
dᵢ is the number of data of the learning data set xᵢ, and
a weight β_{i|j} is the ratio π_{i|j} occupied by the number of data accumulated in the j-th node connected to the i-th node with respect to the number of data accumulated in all nodes connected to the i-th node and the i-th node is calculated by the following expression;
$${π}_{i \vert j} = \frac{{d}_{j}}{{\sum }_{j ∈ \{ i , {ε}_{i} \}} {d}_{j}} . \qquad [ Math . 92 ]$$

4. The variable optimization system according to claim 1, wherein
ψ represents a distribution for each type of learning data accumulated in the n nodes, and
the mini-batch x_{i,MB} represents a mini-batch generated from the learning data set xᵢ in accordance with the distribution ψ.

5. The variable optimization system according to claim 1, wherein
dᵢ is defined as the number of learning data set xᵢ, and
the weight β_{i|j} is the ratio π_{i|j} occupied by the number of data accumulated in the j-th node connected to the i-th node with respect to the number of data accumulated in all nodes connected to the i-th node and the i-th node is calculated by the following expression
$${π}_{i \vert j} = \frac{{d}_{j}}{{\sum }_{j ∈ \{ i , {ε}_{i} \}} {d}_{j}} . \qquad [ Math . 93 ]$$

6. The variable optimization system according to claim 1, wherein the updating a value of
the dual variable z_{i|j} uses at least one of
$${z}_{i \vert j} ← {y}_{j \vert i} \qquad [ Math . 94 ]$$
$$or$$
$${z}_{i \vert j} ← α {y}_{j \vert i} + ( 1 - α ) {z}_{i \vert j} \qquad [ Math . 95 ]$$
(where α is a predetermined constant satisfying 0<α<1).

7. The variable optimization system according to claim 1, wherein the learning data set accumulated in each node in the n nodes indicates statistical deviation of more than a predetermined threshold from another learning data set accumulated in another node in the n nodes.

8. The variable optimization system according to claim 1, wherein communications among the n nodes are asynchronous and sparse based on a predetermined time.
